(19) United States
(12) Patent Application Publication
(10) Pub. No.: US 2026/0190838 A1
(43) Pub. Date: Jul. 2, 2026

(54) Display Panel and Display Device Using the Same

(71) Applicant: LG Display Co., Ltd., Seoul (KR)

(72) Inventors: Hyun Sook Jeon, Paju-si (KR); Yong Cheol Kim, Paju-si (KR)

(21) Appl. No.: 19/429,255

(22) Filed: Dec. 22, 2025

(30) Foreign Application Priority Data
Dec. 31, 2024 (KR) 10-2024-0202839

(51) Int. Cl. H10K 59/80; H10K 59/38

(52) U.S. Cl. CPC H10K 59/8792; H10K 59/38; H10K 59/879

(57) ABSTRACT

A display panel and a display device including the display panel are disclosed herein. The display panel includes a substrate having a plurality of emission parts spaced apart from one another, a light emitting element on the substrate, a lens part on the light emitting element, a color conversion part on the lens part, and a transmittance-variable barrier structure over the color conversion part. The transmittance-variable barrier structure includes barrier walls that correspond to regions among the plurality of emission parts.

### CROSS-REFERENCE TO RELATED APPLICATION

This application claims the priority of Republic of Korea Patent Application No. 10-2024-0202839, filed on Dec. 31, 2024, which is hereby incorporated by reference as if fully set forth herein.

### BACKGROUND

### Field

The present disclosure relates to a display panel and a display device including the same.

### Description of the Related Art

As the fields in which display devices are used are gradually expanding, such display devices are applicable to not only monitors and televisions, but also recently to wearable forms mountable on a viewer to move along with the viewer. In the case of a display device configured to be mountable on a viewer, for display, the display device is included in a mechanism mainly mountable to the viewer's head. In this case, since the display device is configured to be closely fitted to the viewer, the area where the display device is disposed is limited to a confined physical space. For this reason, the display device should have an integrated configuration to achieve clearer, higher-resolution display while also requiring characteristics of high luminance.

Such wearable or mounted display devices exhibit tendencies different from those of large-area display devices in terms of viewing angle, luminance characteristics, and layout density. Therefore, development of different component structures is necessary to achieve high integration and high luminance characteristics.

### SUMMARY

Accordingly, the present disclosure is directed to a display panel and a display device using the same that substantially obviate one or more problems due to limitations and disadvantages of the related art.

The present disclosure relates to a display panel capable of preventing a viewer located outside a predetermined field of view of the display panel from perceiving interference images of other units and achieving a narrow viewing angle, and a display device using the display panel.

Aspects of the present disclosure are not limited to the above-described aspect, and other aspects of the present disclosure not yet described will be more clearly understood by those skilled in the art from the following description.

To achieve these aspects and other advantages and in accordance with the purpose of the disclosure, as embodied and broadly described herein, a display panel includes a substrate having a plurality of emission parts spaced apart from one another, a light emitting element on the substrate, a lens part on the light emitting element, a color conversion part on the lens part, and a transmittance-variable barrier structure over the color conversion part, the transmittance-variable barrier structure including barrier walls that correspond to regions among the plurality of emission parts.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a schematic plan view showing a display device according to one or more embodiments of the present disclosure.

FIG. 2 is a plan view showing a portion of the active area in FIG. 1.

FIG. 3 is a cross-sectional view taken along line I-I′ in FIG. 2.

FIG. 4 is a circuit diagram of one subpixel of FIG. 1 according to one or more embodiments of the present disclosure.

FIG. 5 is a graph depicting light absorption properties of materials with different band gaps according to one or more embodiments of the present disclosure.

FIG. 6 is a cross-sectional view showing a display panel according to one or more embodiments of the present disclosure.

FIG. 7 is a plan view showing one area of the display panel according to one or more embodiments of the present disclosure.

FIG. 8 is a perspective view of a display device according to one or more embodiments of the present disclosure.

FIG. 9 is a plan view showing, from a top side, a state in which a viewer wears the display device of FIG. 8.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a display device of the present disclosure will be described with reference to the accompanying drawings and embodiments.

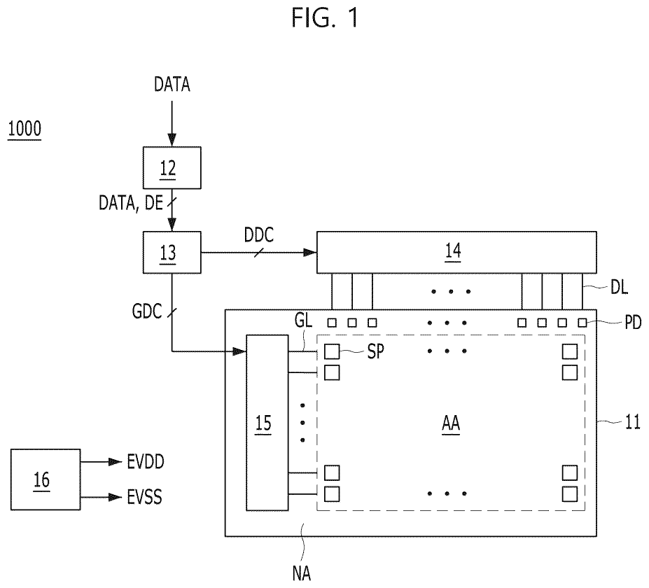

FIG. 1 is a schematic plan view showing a display device according to one or more embodiments of the present disclosure.

As shown in FIG. 1, the display device according to one or more embodiments of the present disclosure, which is designated by reference numeral “1000”, may include a display panel 11, an image processor 12, a timing controller 13, a data driver 14, a scan driver 15, and a power supply 16.

The display panel 11 may display an image, corresponding to a data signal DATA supplied from the data driver 14, a scan signal supplied from the scan driver 15, and power supplied from the power supply 16.

The display panel 11 may include subpixels SP respectively disposed at intersections of a plurality of gate lines GL and a plurality of data lines DL. The structure of the subpixels SP may vary depending on the type of the display device 1000.

For example, the subpixels SP may be formed to have a top emission, bottom emission, or dual emission structure in accordance with the type of the display device 1000. Each subpixel SP refers to a unit that may be formed with a specific color filter or may emit own color without being formed with a color filter. For example, the subpixels SP may include red, green, and blue subpixels. Alternatively, the subpixels SP may include, for example, red, blue, white, and green subpixels. The subpixels SP may have one or more different emission areas in accordance with light emission characteristics thereof. For example, subpixels configured to emit colors different from that of the blue subpixel may have emission areas different from that of the blue subpixel.

One or more subpixels SP may form a unit pixel. For example, the unit pixel may include red, green, and blue subpixels, which may be repeatedly arranged. Alternatively, the unit pixel may include red, green, blue, and white subpixels, which may be repeatedly arranged or may be arranged in a quad-type arrangement. In one or more embodiments of the present disclosure, the color type, arrangement type, and arrangement order of the subpixels may vary depending on emission characteristics of the subpixels, lifespan of the device, specifications of the device, and other factors, but embodiments of the present disclosure are not limited thereto.

The display panel 11 may be divided into an active area AA, where subpixels SP are disposed to display an image (within a dashed-line area), and a non-active area NA surrounding the active area AA. The scan driver 15 may be mounted in the non-active area NA of the display panel 11. Additionally, the non-active area NA may include a pad area PAD including pad electrodes PD.

Here, the active area AA is also referred to as a display area, and the non-active area NA is also referred to as a non-display area.

The image processor 12 may output a data enable signal DE, etc. in addition to the data signal DATA supplied from the outside. In addition to the data enable signal DE, the image processor 12 may also output one or more of a vertical synchronization signal, a horizontal synchronization signal, and a clock signal, but these signals are omitted here for simplicity of description.

The timing controller 13 may receive a drive signal and, in addition, the data signal DATA from the image processor 12. The drive signal may include the data enable signal DE. Alternatively, the drive signal may include the vertical synchronization signal, the horizontal synchronization signal, and the clock signal. The timing controller 13 may output a data timing control signal DDC to control the operation timing of the data driver 14 and a gate timing control signal GDC to control the operation timing of the scan driver 15, based on the drive signal.

The data driver 14 may sample and latch the data signal DATA received from the timing controller 13 in response to the data timing control signal DDC supplied from the timing controller 13. The data driver 14 may convert the resultant data into a gamma reference voltage and may then output the gamma reference voltage.

The data driver 14 may output the data signal DATA through the data lines DL. The data driver 14 may be implemented in the form of an integrated circuit (IC). For example, the data driver 14 may be electrically connected to pad electrodes PD disposed in the non-active area NA of the display panel 11 via a flexible circuit film (not shown).

The scan driver 15 may output a scan signal in response to the gate timing control signal GDC supplied from the timing controller 13. The scan driver 15 may output the scan signal through the gate lines GL. The scan driver 15 may be implemented in the form of an integrated circuit (IC) or may be implemented in the display panel 11 in a gate-in-panel (GIP) manner.

The power supply 16 may output a high-level voltage, a low-level voltage, etc. for driving of the display panel 11. The power supply 16 may supply the high-level voltage to the display panel 11 via a first power line EVDD (a drive power line or a pixel power line) and may supply the low-level voltage to the display panel 11 via a second power line EVSS (an auxiliary power line or a common power line).

The display panel 11 is divided into the active area AA and the non-active area NA, and may include a plurality of subpixels SP defined by the gate lines GL and the data lines DL formed in the active area AA in a matrix form while intersecting each other.

The subpixels SP may include subpixels configured to emit light of at least two colors among red, green, blue, yellow, magenta, and cyan. Additionally, a plurality of subpixels SP may be formed with specific kinds of color filters or may emit their own colors without being formed with color filters. However, embodiments of the present disclosure are not limited to these configurations, and the color type, arrangement type, and arrangement order of the subpixels SP may vary diversely depending on emission characteristics of the subpixels, lifespan of the device, specifications of the device, and other factors.

Each subpixel SP may include an emission part REM, GEM, or BEM configured to emit light, and a non-emission part NEA surrounding the emission part.

Hereinafter, a structure of the display panel according to one or more embodiments of the present specification will be described with reference to the drawings.

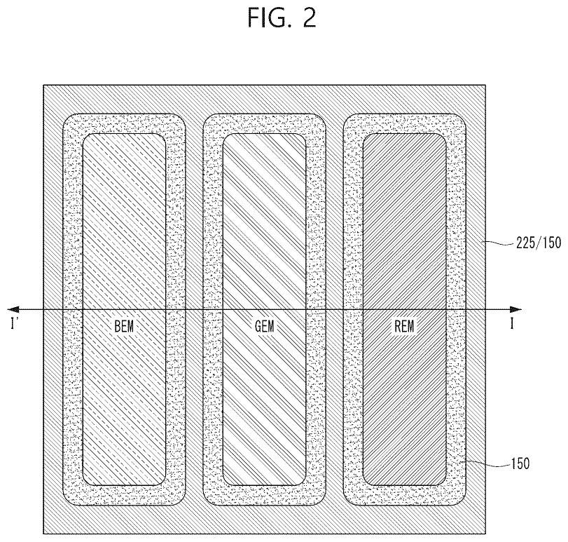

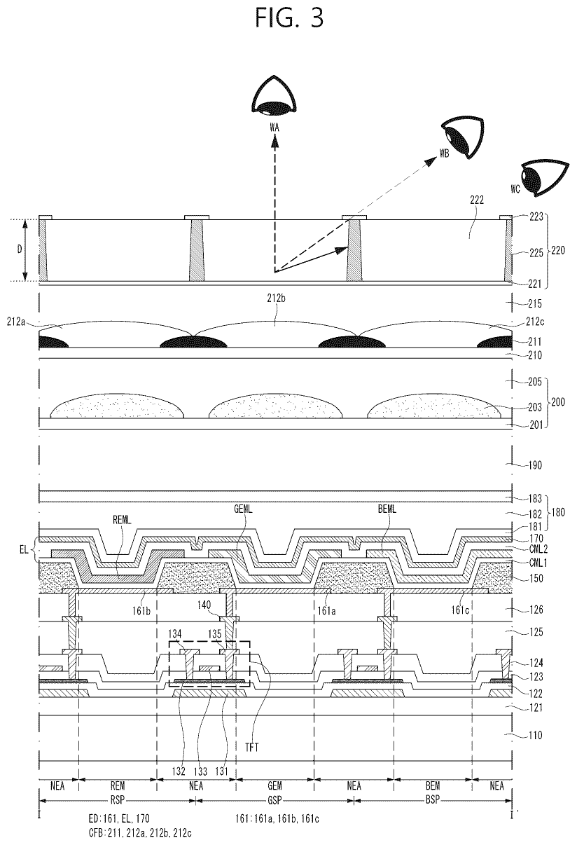

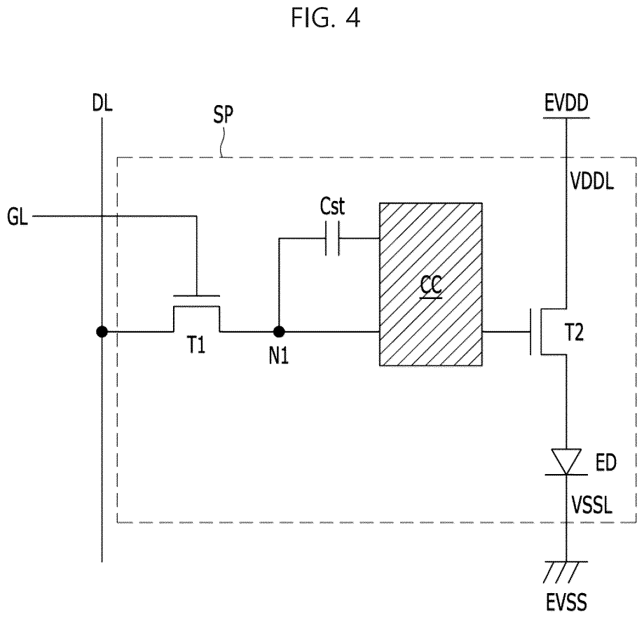

FIG. 2 is a plan view showing a portion of the active area in FIG. 1. FIG. 3 is a cross-sectional view taken along line I-I′ in FIG. 2. FIG. 4 is a circuit diagram of one subpixel of FIG. 1 according to one or more embodiments of the present disclosure.

As shown in FIGS. 2 and 3, the display panel according to one or more embodiments of the present disclosure includes a substrate 110 with a plurality of emission parts REM, GEM, and BEM spaced apart from one another, a light emitting element ED provided on the substrate 110, a lens part 200 provided on the light emitting element ED, and a color conversion part CFB (211, 212a, 212b, and 212c) provided on the lens part 200.

The emission parts REM, GEM, and BEM disposed on the substrate 110 may include, for example, a red emission part REM, a green emission part GEM, and a blue emission part BEM sequentially disposed side by side.

The emission parts REM, GEM, and BEM may be defined as open areas, that is, openings, of a bank 150. In addition, an area where the bank 150 is disposed may be defined as a non-emission part NEA.

Each light emitting element ED includes a first electrode 161 (161b, 161a, or 161c) corresponding to one of the plurality of emission parts REM, GEM, and BEM, an intermediate layer EL, and a second electrode 170.

Here, the bank 150, which defines the emission parts REM, GEM, and BEM, covers edges of the first electrodes 161 (161a, 161b, and 161c).

The display device of one or more embodiments of the present disclosure includes a transmittance-variable barrier structure 220 disposed over the color conversion part CFB (211, 212a, 212b, and 212c) while including barrier walls 225.

The barrier walls 225 are spaced apart from the emission parts REM, GEM, and BEM and may have a shape surrounding the emission parts REM, GEM, and BEM. Here, each barrier wall 225 may extend in the form of a single line between neighboring different emission parts.

The barrier walls 225 may overlap with the non-emission part NEA and may have a matrix-shaped planar structure with openings larger than respective emission parts REM, GEM, and BEM of the subpixels SP throughout the active area AA. Throughout the active area AA, the barrier walls 225 may have a seamless, integrated planar structure without division.

The barrier walls 225 included in the transmittance-variable barrier structure 220 are disposed to correspond to regions among the plurality of emission parts REM, GEM, and BEM, respectively. FIGS. 2 and 3 illustrate an example in which the barrier walls 225 are disposed between neighboring ones of the emission parts REM, GEM, and BEM, respectively. However, embodiments of the present disclosure are not limited to the above-described configurations. For example, the barrier walls 225 may be disposed for every n (n being a natural number equal to or greater than 2) emission parts.

The spacing between the barrier walls 225 may correspond to a pitch of the lens part 200.

The spacing between the barrier walls 225 may be adjusted in accordance with the field of view (FOV) of a front viewer WA. For example, when the field of view (FOV) of the front viewer WA corresponds to m (m being a natural number) subpixels, the barrier walls 225 may be disposed for every m subpixels.

The spacing between the barrier walls 225 may vary depending on the viewing angle range to be covered by the display panel. As the viewing angle range increases, the spacing between the barrier walls 225 may be increased. For example, when the front viewing angle is set to ±25° from a front side, a viewer WC located outside the front viewing angle range of ±25° may be prevented from receiving light passing through the transmittance-variable barrier structure 220 because the light is blocked by the barrier walls 225. Accordingly, normal image viewing is only possible within a predetermined viewing angle range from outside the display panel provided with the transmittance-variable barrier structure 220, and the barrier walls 225 prevent image transmission to viewers WC outside the predetermined viewing angle range.

The transmittance-variable barrier structure 220 as described above may prevent viewers outside the FOV range from perceiving an interference image of a view adjacent to a normal view.

In particular, in a structure having no barrier, viewers outside the predetermined viewing angle may perceive interference views adjacent to a normal view due to light beams emitted as strabismus light caused by the curvature of the lens part 200. However, in the display panel according to one or more embodiments of the present disclosure, the transmittance-variable barrier structure 220 is disposed at an outermost edge of the display panel, as shown in FIG. 3, thereby preventing transmission of strabismus light to viewers outside the predetermined viewing angle range.

The barrier walls 225 are configured to shield strabismus light, and is disposed in the non-emission part NEA while having a smaller width than the width of the bank 150 and the width of a light shielding layer 211, so as not to have influence on emission of front light.

The transmittance-variable barrier structure 220 includes a first electrode structure 221 and a second electrode structure 223 facing each other under the condition that the barrier walls 225 are disposed between the first electrode structure 221 and the second electrode structure 223.

Each of the first and second electrode structures 221 and 223 may include a transparent electrode material such as indium tin oxide (ITO), indium zinc oxide (IZO), or indium tin zinc oxide (ITZO).

The first electrode structure 221 may have a plate shape, whereas the second electrode structure 223 may have a shape of divisional patterns respectively corresponding to barrier walls 225 surrounding the plurality of emission parts REM, GEM, and BEM.

Each barrier wall 225 includes an organic semiconductor material. Accordingly, the barrier wall 225 may apply a voltage difference between the first electrode structure 221 and the second electrode structure 223 in order to enable a vertical electric field to be generated between the first electrode structure 221 and the second electrode structure 223. The energy band gap of the barrier wall 225 may be adjusted for blocking and/or absorbing light. As a result, the barrier wall 225 functions to block at least a part or the entirety of light in a visible light spectrum.

In the display panel of FIG. 3, the first electrode structure 221 and the second electrode structure 223 may extend to the non-active area NA (see FIG. 1), allowing different voltages to be applied in the non-active area NA.

The voltage difference applied between the first electrode structure 221 and the second electrode structure 223 may be selectively adjusted in accordance with ambient light conditions.

The barrier wall 225 includes an organic semiconductor material capable of varying an energy band gap thereof in accordance with the wavelength of light incident thereon, and the energy band gap adjustable in accordance with voltage application may be 1.5 to 3.5 eV.

When a voltage difference is applied between the first electrode structure 221 and the second electrode structure 223, the barrier wall 225 may exhibit light-absorbing or light-blocking properties for light at wavelengths corresponding to at least a part of the visible light spectrum.

The organic semiconductor material constituting the barrier wall 225 may enable light sensing and may allow easy control of the energy band gap, differently from a black resin generally constituting a louver structure included in a light control film. Additionally, since the organic semiconductor material does not produce outgassing or similar byproducts during the process, the organic semiconductor material has an advantage in that the organic semiconductor material is usable as an environmentally friendly material.

Furthermore, in the display panel according to one or more embodiments of the present disclosure, the transmittance-variable barrier structure 220 is disposed at the outermost edge of the display panel and, as such, has an advantage of easy sensing of external light.

In the transmittance-variable barrier structure 220, the first electrode structure 221 may contact lower surfaces of the barrier walls 225, whereas the second electrode structure 223 may contact, at the divisional patterns thereof, upper surfaces of the barrier walls 225, respectively. That is, the vertical electric field generated by the voltage difference between the first and second electrode structures 221 and 223 may directly vary the energy band gap of the organic semiconductor material constituting the barrier walls 225.

Additionally, the second electrode structure 223 may have, at each divisional pattern thereof, a greater area than the upper surface of the barrier wall 225 corresponding to the divisional pattern in order to protect the barrier wall 225 and to secure stable electrical characteristics of the barrier wall 225.

Additionally, in the transmittance-variable barrier structure 220, a transparent insulating material 222 may be filled among the barrier walls 225 and the transparent insulating material 222 may have a height corresponding to a height D of each barrier wall 225.

The height of the barrier wall 225 may be 2 to 5 μm. This height of the barrier wall 225 is a height determined taking into consideration prevention of viewers outside the field of view (FOV) range from perceiving interference views. That is, when the height of the barrier wall 225 is less than 2 μm, the effectiveness in prevention of viewers outside the field of view (FOV) range from perceiving interference views may be reduced. Conversely, when the height of the barrier wall 225 exceeds 5 μm, the viewing angle of a main viewer may become too narrow.

The transmittance-variable barrier structure 220 may block light emission outside a predetermined viewing angle range, and the organic semiconductor material of the barrier wall 225 may sense external light.

Meanwhile, in each of the subpixels RSP, GSP, and BSP, the light emitting element ED thereof includes a pixel circuit shown in FIG. 4 and, as such, may be selectively driven.

As shown in FIG. 4, each subpixel SP (RSP, GSP, or BSP) in the active area AA may include, for example, a first transistor T1, a second transistor T2, a storage capacitor Cst, a compensation circuit CC, and the light emitting element ED.

For example, the first transistor T1 may be a switching transistor, and the second transistor T2 may be a driving transistor.

A first electrode of the first transistor T1 (for example, a drain electrode) is electrically connected to a data line DL, and a second electrode of the first transistor T1 (for example, a source electrode) is electrically connected to a first node N1. A gate electrode of the first transistor T1 is electrically connected to a gate line GL. In response to a scan signal supplied via the gate line GL, the first transistor T1 transmits a data signal supplied through the data line DL to the first node N1.

The storage capacitor Cst is electrically connected to the first node N1 and, as such, is charged by a voltage applied to the first node N1.

A first electrode of the second transistor T2 (for example, a drain electrode) receives a high-level drive voltage EVDD through a high-level voltage line VDDL, and a second electrode of the second transistor T2 (for example, a source electrode) is electrically connected to a first electrode of the light emitting element ED (for example, an anode AND). The second transistor T2 may control the amount of drive current flowing through the light emitting element ED in accordance with a voltage applied to a gate electrode thereof.

A semiconductor layer of the first transistor T1 and/or the second transistor T2 may include silicon such as amorphous silicon (a-Si), polycrystalline silicon (poly-Si), low-temperature polycrystalline silicon (LT poly-Si) or the like, or an oxide such as indium-gallium-zinc oxide (IGZO) or the like, without being limited thereto. At least one of the first and second transistors T1 and T2 may include an oxide semiconductor layer and, as such, may be formed at a low temperature, may maintain amorphous characteristics, and may have high mobility, as compared to other materials.

The light emitting element ED outputs light corresponding to the drive current. The light emitting element ED may output light of a color selected from red, green, blue, and white.

The light emitting element ED may include the first electrode AND, an intermediate layer EL disposed on the first electrode AND, and a second electrode CAT configured to supply a common voltage. As described with reference to FIG. 2, the intermediate layer EL includes a hole-related common transport layer CML1, color selection layers RFL, GFL, BFL, and AFL, and an electron-related common transport layer CML2. Accordingly, each subpixel emits light of a color produced from a corresponding one of the color selection layers RFL, GFL, BFL, and AFL.

The second electrode CAT of the light emitting element ED receives a low-level voltage EVSS or a ground voltage via a low-level voltage line VSSL. The low-level voltage line VSSL may be disposed in the non-active area NA. In some cases, the low-level voltage line VSSL may also be disposed in the active area AA in order to prevent non-uniformity of the low-level voltage EVSS generated in the active area AA. The low-level voltage EVSS is also referred to as a common voltage.

The compensation circuit CC may be provided within the subpixel SP in order to compensate the threshold voltage or other characteristics of the second transistor T2. The compensation circuit CC may be constituted by one or more transistors. The compensation circuit CC may include one or more transistors and a capacitor and may be diversely configured in accordance with a compensation method thereof. The subpixel, which includes the compensation circuit CC, may include a circuit having various structures with different numbers of transistors and/or capacitors, such as 3T1C, 4T2C, 5T2C, 6T1C, 6T2C, 7T1C, 7T2C, etc.

Meanwhile, the pixel circuit shown in FIG. 4 may be provided for every subpixel. A thin film transistor TFT shown in FIG. 3 may be, for example, the second transistor T2 of FIG. 4.

Next, configurations other than the transmittance-variable barrier structure 220 will be sequentially described.

The substrate 110, on which the subpixels RSP, GSP, and BSP are disposed, may be constituted by a single layer or multiple layers.

The substrate 110 may include at least one of a glass substrate, a plastic film, or a metal plate, which has certain support strength. The substrate 110 may also be made of a flexible material. For example, when the substrate 110 is constituted by multiple layers, the substrate 110 may have a laminated structure of a first organic film, an inorganic insulating layer, and a second organic film. The outermost first organic film may serve to prevent penetration of external impurities and may have a protective function. The second organic film may facilitate planarization of a surface on which an inner array structure will be formed, and may prevent inward transfer of charges or impurities from the outside.

On the substrate 110, a first insulating layer 121 may be provided. The first insulating layer 121 may function as a buffer layer or an active buffer layer. The buffer layer or the active buffer layer may prevent impurities from moving upwards from lower sides of wirings and an active layer included in the inner array, and may also function to support and protect an upper configuration. The first insulating layer 121 may be constituted by multiple layers.

On the first insulating layer 121, a thin film transistor TFT and a storage capacitor may be disposed for each of the subpixels RSP, GSP, and BSP.

On the first insulating layer 121, a light shielding layer 131 may be provided to prevent light from being transmitted to an active layer 132 of the thin film transistor TFT from below.

A second insulating layer 122 may be disposed between the light shielding layer 131 and the active layer 132 to provide insulation.

The thin film transistor TFT may be disposed at each of the plurality of subpixels on the second insulating layer 122. For example, the thin film transistor TFT may include the active layer 132, a gate electrode 133 configured to overlap with the active layer 132. A third insulating layer 123 is disposed between the active layer 132 and the gate electrode 133. First and second source/drain electrodes 134 and 135 are connected to opposite sides of the active layer 132, respectively.

For example, the storage capacitor may include a first storage electrode and a second storage electrode overlapping each other. At least one of the first storage electrode or the second storage electrode may be made of the same material as the active layer 132, whereas the other of first storage electrode and the second storage electrode may include the same material as at least one of the gate electrode 133, the first and second source/drain electrodes 134 and 135, or the light shielding layer 131.

The third insulating layer 123 between the active layer 132 and the gate electrode 133 may function as a gate insulating layer.

The active layer 132 may include, for example, a silicon-based semiconductor or an oxide semiconductor. The silicon-based semiconductor may include crystalline and/or amorphous silicon. The oxide semiconductor may include at least one of gallium oxide, tin oxide, zinc oxide, indium oxide, iron oxide, or indium-gallium-zinc oxide. In some cases, the oxide semiconductor layer may be constituted by a plurality of layers of different materials or with different compositions. Each subpixel may include a plurality of thin film transistors. In this case, the plurality of thin film transistors may be disposed on different layers. For example, each subpixel on the substrate 110 may include a plurality of thin film transistors with different active layers. For example, a first thin film transistor may have a silicon-based active layer disposed closer to the substrate 110, whereas a second thin film transistor may have an active layer made of an oxide semiconductor and disposed above the first thin film transistor.

The active layer 132 may include a channel region overlapping with the gate electrode 133, and source/drain regions respectively connected to the first and second source/drain electrodes 134 and 135. One of the first and second source/drain electrodes 134 and 135 may function as a source electrode of the thin film transistor TFT, whereas the other of the first and second source/drain electrodes 134 and 135 may function as a drain electrode of the thin film transistor TFT.

The third insulating layer 123 may be selectively disposed over the channel region of the active layer 132, or may be provided at the entire surface of the substrate 110, except for regions through which the first and second source/drain electrodes 134 and 135 extend. The third insulating layer 123 may function to insulate the active layer 132 and the gate electrode 133 from each other. The third insulating layer 123 may be made of an inorganic insulating material. For example, the third insulating layer 123 may be constituted by a silicon oxide (SiOₓ) layer, a silicon nitride (SiNₓ) layer, a silicon oxynitride (SiOₓN_{y}) layer, or a multilayer structure thereof.

On the third insulating layer 123, the gate electrode 133 may be formed. The gate electrode 133 may be disposed to face the active layer 132. The third insulating layer 123 is interposed between the active layer 132 and the gate electrode 133.

A fourth insulating layer 124, which covers and protects the gate electrode 133, may be formed on the gate electrode 133. Additionally, the fourth insulating layer 124 may serve to protect at least one electrode of the thin film transistor TFT, for example, the gate electrode 133, and the active layer 132. The fourth insulating layer 124 may be made of an inorganic insulating material. For example, the fourth insulating layer 124 may be constituted by a silicon oxide (SiOₓ) layer, a silicon nitride (SiNₓ) layer, a silicon oxynitride (SiOₓN_{y}) layer, or a multilayer structure thereof.

The first source/drain electrode 134 and the second source/drain electrode 135 may be disposed on the fourth insulating layer 124. The fourth insulating layer 124 and the third insulating layer 123 may include contact holes to bring the first and second source/drain electrode 134 and 135 into contact with opposite ends of the active layer 132, respectively. For formation of the contact holes, regions of the fourth insulating layer 124 and the third insulating layer 123 corresponding to respective contact holes may be removed.

The gate electrode 133 and the first and second source/drain electrodes 134 and 135 may each be constituted by a single layer or multiple layers.

When the gate electrode 133 and the first and second source/drain electrodes 134 and 135 have single-layer structures, respectively, they may be made of one material selected from the group consisting of molybdenum (Mo), aluminum (Al), chromium (Cr), gold (Au), titanium (Ti), nickel (Ni), neodymium (Nd), copper (Cu), and alloys thereof. Additionally, when the gate electrode 133 and the first and second source/drain electrodes 134 and 135 have multilayer structures, respectively, they may each be constituted by a double-layer structure of molybdenum/aluminum-neodymium, molybdenum/aluminum, titanium/aluminum, or copper/molybdenum. Alternatively, the gate electrode 133 and the first and second source/drain electrodes 134 and 135 may each be constituted by a triple-layer structure of molybdenum/aluminum-neodymium/molybdenum, molybdenum/aluminum/molybdenum, titanium/aluminum/titanium, or molybdenum-titanium/copper/molybdenum-titanium.

However, embodiments of the present disclosure are not limited to the above-described examples. The gate electrode 133 and the first and second source electrodes 134 and 135 may be formed to have a multilayer structure made of one material selected from the group consisting of molybdenum (Mo), aluminum (Al), chromium (Cr), gold (Au), titanium (Ti), nickel (Ni), neodymium (Nd), copper (Cu), and alloys thereof.

The first to fourth insulating layers 121, 122, 123, and 124 may each be made of an inorganic insulating material. For example, the inorganic insulating layer may be at least one of a silicon oxide (SiOₓ) layer, a silicon nitride (SiNₓ) layer, or a silicon oxynitride (SiOₓN_{y}) layer.

A first planarization layer 125 and a second planarization layer 126 may be provided on the first to fourth insulating layers 121, 122, 123, and 124. The first planarization layer 125 may be formed with a contact hole, and a connection electrode 140, which is configured to be connected to the second source/drain electrode 135, may be provided in the contact hole. The second planarization layer 126 may be disposed to cover the connection electrode 140 and the first planarization layer 125. The first and second planarization layers 125 and 126 may each include an organic material. The organic material may include one or more of acrylic resin, phenolic resin, polyimide resin, unsaturated polyester resin, polyamide resin, benzocyclobutene, polyphenylene resin, and polyphenylene sulfide resin.

The connection electrode 140 may be formed to have a multilayer structure made of one material selected from the group consisting of molybdenum (Mo), aluminum (Al), chromium (Cr), gold (Au), titanium (Ti), nickel (Ni), neodymium (Nd), copper (Cu), and alloys thereof. However, embodiments of the present disclosure are not limited to the above-described configuration. In some cases, the connection electrode 140 may be omitted. When the connection electrode 140 is omitted, one of the first and second source/drain electrodes 134 and 135 may be directly connected to the first electrode 161 (161a, 161b, or 161c) of the light emitting element ED.

The light emitting element ED is constituted through stacking of the first electrode 161 (161a, 161b, or 161c), the intermediate layer EL, and the second electrode 170.

The first electrode 161 (161a, 161b, or 161c) may serve as an anode. The first electrode 161 (161a, 161b, or 161c) extends through the second planarization layer 126 and the first planarization layer 125 and is connected to the transistor TFT. In the shown example, the connection electrode 140 is shown as being additionally provided between the first electrode 161 (161a, 161b, or 161c) and the transistor TFT, and connection between the transistor TFT and the connection electrode 140 and connection between the connection electrode 140 and the first electrode 161 (161a, 161b, or 161c are made. However, the second source/drain electrode 135 of the transistor TFT and the first electrode 161 (161a, 161b, or 161c) of the light emitting element ED may be directly connected to each other under the condition that the connection electrode 140 is omitted.

The first electrode 161 (161a, 161b, or 161c) may include a metal material with high reflectivity. For example, the first electrode 161 (161a, 161b, or 161c) may be formed to have a multilayer structure such as a laminated structure Ti/Al/Ti of aluminum and titanium, a laminated structure ITO/Al/ITO of aluminum and ITO, an alloy of Ag/Pd/Cu (APC), a laminated structure ITO/APC/ITO of an APC alloy and ITO, and a laminated structure Ag/MoTi of an alloy of silver and molybdenum/titanium or may be formed to have a single-layer structure made of a material selected from silver (Ag), aluminum (Al), molybdenum (Mo), gold (Au), magnesium (Mg), calcium (Ca), barium (Ba), and alloys of two or more thereof. The first electrode 161 (161a, 161b, or 161c) may be referred to as a reflective electrode.

The intermediate layer EL is provided on the first electrode 161 (161a, 161b, or 161c). The intermediate layer EL may include a hole-related first common layer CML1 such as a hole injection layer and a hole transport layer, an organic light emitting layer EML, and an electron-related second common layer CML2 such as an electron transport layer and an electron injection layer.

As shown in FIG. 3, the organic light emitting layer EML may include a red light emitting layer REML for the red subpixel RSP, a green light emitting layer GEML for the green subpixel GSP, and a blue light emitting layer BEML for the blue subpixel BSP in a divisional manner. The red light emitting layer REML may be disposed at the red subpixel RSP in a patterned manner. The green light emitting layer GEML may be disposed at the green subpixel GSP in a patterned manner. The blue light emitting layer BEML may be disposed at the blue subpixel BSP in a patterned manner. However, these configurations are only one example.

In some cases, the intermediate layer EL may have the same tandem type configuration of a plurality of stacks for the subpixels RSP, GSP, and BSP. In this case, the intermediate layer EL of the light emitting element ED includes a charge generation layer disposed among the plurality of stacks, and each stack may include one or more light emitting layers. When the intermediate layer EL has the same structure for the subpixels RSP, GSP, and BSP, the light emitting element ED emits white light, and red, green, and blue color filters 182a, 182b, and 182c of the color conversion part CFB may selectively emit light of colors respectively corresponding to the subpixels.

The edges of the first electrodes 161 (161a, 161b, and 161c) of respective subpixels RSP, GSP, and BSP may overlap with the bank 150. Regions of the first electrodes 161 (161a, 161b, and 161c) exposed from the bank 150 may be the emission parts REM, GEM, and BEM. The bank 150 is configured to open the emission parts REM, GEM, and BEM of respective subpixels RSP, GSP, and BSP. The bank 150 may include an organic or inorganic insulating material.

When voltages are applied to the first electrode 161 (161a, 161b, or 161c) and the second electrode 170, holes and electrons move to the organic light emitting layer through corresponding ones of the hole injection layer and the hole transport layer, and the electron injection layer and the electron transport layer. In the organic light emitting layer, holes and electrons are recombined to form excitons. As the excitons then relax from an excited state to the ground state, light is emitted.

A plurality of layers or at least one layer included in the intermediate layer EL (REL, GEL, and BEL) may be provided in common in the entirety of the active area AA.

The second electrode 170 may be a common layer disposed at the subpixels SP in common to apply the same voltage. To achieve this, the second electrode 170 may extend from the display area AA to a portion of the non-active area NA.

The second electrode 170 may be a transmissive electrode. The second electrode 170 may include a transparent conductive material (TCO) such as indium tin oxide (ITO) or indium zinc oxide (IZO) or a semi-transmissive conductive material such as magnesium (Mg), silver (Ag), or an alloy of magnesium (Mg) and silver (Ag). When the second electrode 170 includes a semi-transmissive conductive material, luminous efficacy may be enhanced by virtue of micro cavities. When the second electrode 170 includes the semi-transmissive conductive material, the thickness thereof may be very small to allow light transmission.

The first electrode 161 (161a, 161b, or 161c) may include a reflective electrode component to prevent light generated from the intermediate layer EL from being transferred to a constituent element having light shielding properties beneath the first electrode 161 (161a, 161b, or 161c). Light generated from the intermediate layer EL may resonate between the second electrode 170 and the first electrode 161 (161a, 161b, or 161c). Ultimately, the light may be emitted upwards through the second electrode 170. Since the first electrode 161 (161a, 161b, or 161c) includes a reflective electrode component, the emission part REM, GEM, or BEM corresponding to the first electrode 161 (161a, 161b, or 161c) may radiate light even when the first electrode 161 (161a, 161b, or 161c) overlaps with the wirings and the transistor TFT, without being affected by such arrangement. Accordingly, the light emitted from the light emitting element ED may be observed.

The light emitting display device according to one or more embodiments of the present disclosure is implemented in a top-emission type in which the emission direction is upward. In this case, the first electrode 161 (161a, 161b, or 161c) includes a reflective electrode component and, as such, light generated from the intermediate layer EL resonates while being reflected and re-reflected between the first electrode 161 (161a, 161b, or 161c) and the second electrode 170. Ultimately, the light is emitted through the second electrode 170.

An encapsulation layer 180 may be provided on the second electrode 170 to protect the light emitting element ED. The encapsulation layer 180 may have a single-layer structure or a multilayer structure. When the encapsulation layer 180 has a multilayer structure, the encapsulation layer 180 may be configured through alternate stacking of at least one inorganic encapsulation layer 181 or 183 and at least one organic encapsulation layer 182. The inorganic encapsulation layers 181 and 183 may function to prevent moisture ingress, and the organic encapsulation layer 182 may function to cover particles and to provide surface planarization. The organic encapsulation layer 182 may be disposed inside the inorganic encapsulation layers 181 and 183 on a plane. In this case, the inorganic encapsulation layers 181 and 183 may prevent moisture ingress from the sides of the substrate 110.

A transparent protective layer 190 may be provided on the encapsulation layer 180. The transparent protective layer 190 may planarize an upper surface on which the lens part 200 will be formed. The transparent protective layer 190 may also maintain a predetermined distance or more between the light emitting element ED and the lens part 200. Accordingly, the degree of refraction of light, which is emitted from the emission element ED, when the light meets a curved lens surface of the lens part 200, may be adjusted.

The lens part 200 may include a lens buffer layer 201, a lens layer 203, and a lens protective layer 205. For example, the lens layer 203 may include a high-refractive-index material and the lens protective layer 205 may include a low-refractive-index material, and, as such, a refraction effect may be exhibited at a curved lens surface on a surface of the lens layer 203.

A color conversion part CFB is disposed on the lens part 200. The color conversion part CFB may include a color conversion buffer layer 210, a light shielding layer 211, color conversion layers 212a, 212b and 212c, and a color conversion protective layer 215, which are disposed over the lens part 200.

In some cases, the color conversion buffer layer 210 may be omitted.

The light shielding layer 211 is disposed to correspond to the non-emission part NEA. For example, the light shielding layer 211 may include at least one of a light-absorbing material, a black material, or a light-shielding material. The light shielding layer 211 may fully shield light in the visible spectrum. Alternatively, the light shielding layer 211 may be constituted by laminating materials shielding light at wavelengths corresponding to at least a part of the visible light spectrum.

The color conversion layers 212a, 212b, and 212c transmit light in a predetermined wavelength band while absorbing or shielding light of other wavelength bands. For example, a red color filter 212a may be disposed to correspond to the red light emission part REM of the red subpixel RSP, a green color filter 212b may be disposed to correspond to the green light emission part GEM of the green subpixel GSP, and a blue color filter 212c may be disposed to correspond to the blue light emission part BEM of the blue subpixel BSP.

The color conversion layers 212a, 212b, and 212c may extend to the non-emission part NEA disposed outside the emission part REM, GEM, and BEM, respectively, thereby performing color conversion functions even for strabismus light.

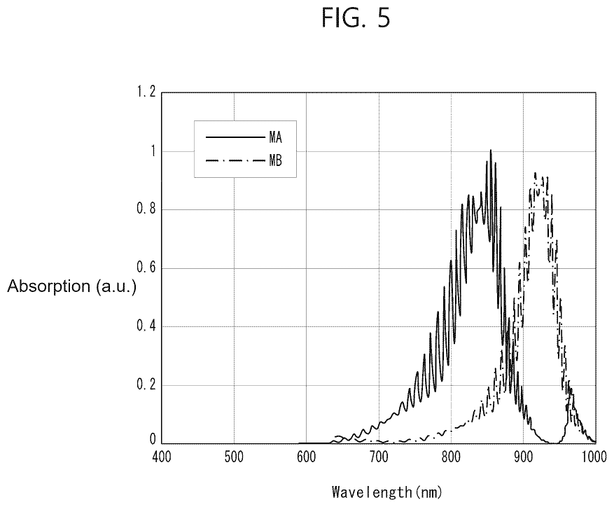

FIG. 5 is a graph depicting light absorption properties of materials with different band gaps in accordance with one or more embodiments of the present disclosure.

In FIG. 5, a first material MA has an energy band gap of 1.44 eV, and a second material MB has an energy band gap of 1.35 eV. The graph of FIG. 5 shows that the first material MA with a greater energy band gap than the second material MB exhibits light absorption properties in a wavelength band near the wavelength band of the visible light.

In the display panel and the display device according to one or more embodiments of the present disclosure, the barrier wall may be made of an organic semiconductor material with an energy band gap of about 1.5 to 3.5 eV and, as such, may have light absorption properties in the visible light spectrum shorter than that of the first material MA.

The energy band gap range of 1.5 eV to 3.5 eV may provide light absorption properties in the visible light spectrum.

Next, a display panel according to one or more other embodiments of the present disclosure will be described.

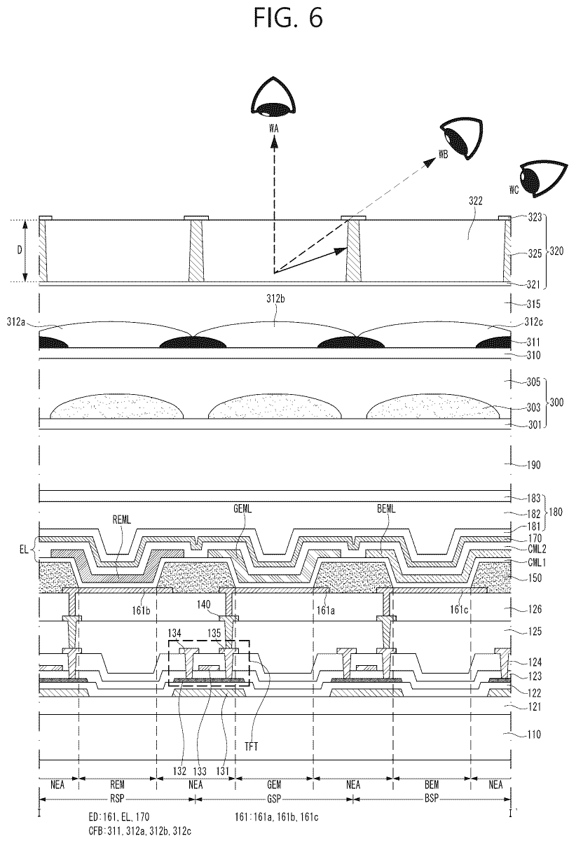

FIG. 6 is a cross-sectional view showing the display panel according to one or more embodiments of the present disclosure.

The display panel of FIG. 6 has the same configurations as the display panel described above with reference to FIG. 3 in terms of the part beneath the color conversion part CFB. Therefore, no description will be given of the same configurations.

A lens part 300 may include a lens buffer layer 301, a lens layer 303, and a lens protective layer 305.

A color conversion part CFB is disposed on the lens part 300. The color conversion part CFB may include a color conversion buffer layer 310, a light shielding layer 311, color conversion layers 312a, 312b, and 312c, and a color conversion protective layer 315, which are disposed over the lens part 300.

As shown in FIG. 6, a transmittance-variable barrier structure 320 includes a first electrode structure 321 and a second electrode structure 323 facing each other. A barrier wall 325 is disposed between the first electrode structure 321 and the second electrode structure 323.

The transmittance-variable barrier structure 320 of FIG. 6 has partial transmittance in a vertical direction in accordance with adjustment of the energy band gap of an organic semiconductor material constituting the barrier wall 325.

When the barrier wall 325 has partial transmittance, a configuration opaque in a predetermined viewing angle range may be omitted, leading to an enhancement in luminance within the predetermined viewing angle range. Furthermore, beyond the predetermined viewing angle range, transmission of interference view images through the barrier wall 325 is prevented. Accordingly, it may be possible to prevent viewers WC outside the predetermined viewing angle range from perceiving interference images and perceiving distorted images.

Meanwhile, at least one side of the first electrode structure 321 and the second electrode structure 323 of the transmittance-variable barrier structure 320 may be maintained in a floating state. In this case, the energy band gap of the barrier wall 325 is adjusted in accordance with the light intensity sensed by the barrier wall 325 in accordance with ambient illuminance of the exterior where the display panel is located. As a result, the visible light spectrum shielded or absorbed by the barrier wall 325 is adjusted and, as such, light outside the predetermined viewing angle range may be shielded.

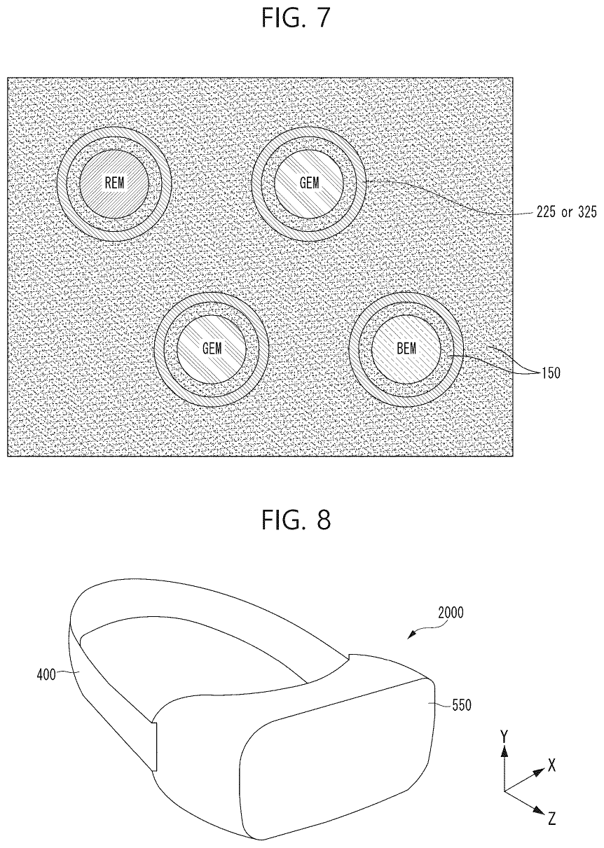

FIG. 7 is a plan view showing one area of the display panel according to one or more embodiments of the present disclosure.

The display panel of FIG. 7 shows an example in which barrier walls 225 or 325 are independently configured for respective emission parts REM, GEM, and BEM configured to emit different colors. In this case, the barrier walls 225 or 325 disposed for each of the emission parts REM, GEM, and BEM are spaced apart from the barrier walls 225 or 325 surrounding the emission parts neighboring thereto.

The barrier walls 225 or 325 shown in FIG. 7 are disposed in the form of annular islands surrounding respective emission parts REM, GEM, and BEM or adjacent ones of the emission parts REM, GEM, and BEM. The barrier walls 225 or 325 are disposed to have a width narrower than those of the bank 150 and the light shielding layer 211 or 311 configured to overlap with the barrier walls 225 or 325, in order to prevent a reduction in transmittance in the vertical direction.

In the example of FIG. 7, green emission parts GEM are diagonally disposed, and are more densely disposed, as compared to red emission parts REM and blue emission parts BEM. The reason why the green emission parts GEM are configured to have a greater density is because green contributes significantly to expression of white. However, embodiments of the present disclosure are not limited to the above-described configuration.

Additionally, the example shown in FIG. 7 shows the case in which each of the emission parts REM, GEM, and BEM has a circular shape. However, this is just one example, and embodiments of the present disclosure are not limited to the example. Each of the emission parts REM, GEM, and BEM may have a polygonal shape other than the circular shape, and in some cases, a portion of the polygonal shape or all corners of the polygonal shape may be rounded. Additionally, the size and density of each of the emission parts REM, GEM, and BEM may vary depending on requirements for light emission expression.

The barrier walls 225 or 325 of FIG. 7 as described above are included in the transmittance-variable barrier structure described with reference to FIG. 3 or FIG. 6 to prevent interference image perception by viewers outside the predetermined viewing angle range.

Hereinafter, an example of a display device, to which the display panel according to one or more embodiments of the present disclosure is applied, will be described.

The display panel according to one or more embodiments of the present disclosure may have an eyeglass type, helmet type, or band-type appearance, as in a head-mounted display device.

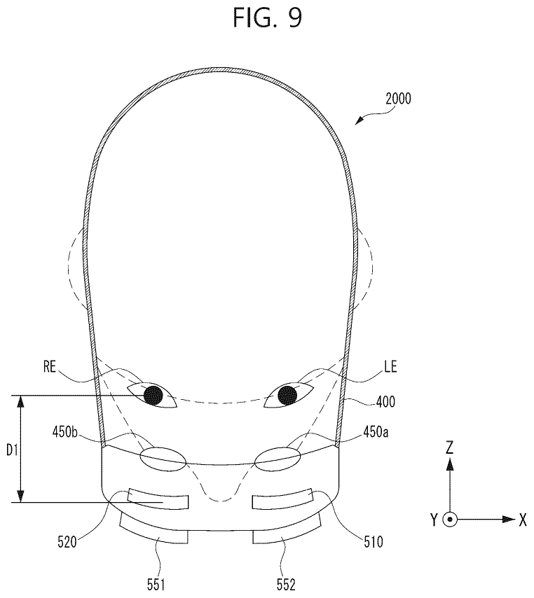

FIG. 8 is a perspective view of a display device according to one or more embodiments of the present disclosure. FIG. 9 is a plan view showing, from a top side, a state in which a viewer wears the display device of FIG. 8.

As shown in FIGS. 8 and 9, the display device according to one or more embodiments of the present disclosure, which is designated by reference numeral “2000”, is a head-mounted display device. The display device 2000 includes a body 550 corresponding to both eyes RE and LE of a viewer, first and second inner display panels 510 and 520 provided at an inner surface of the body 550 to correspond to both eyes RE and LE of the viewer, respectively, outer display panels 551 and 552 provided at an outer surface of the body 550, and a connector 400 configured to interconnect opposite sides of the body 550.

In this case, the body 550 has, in an X-Y plane, a surface area sufficient to cover the area of a face where both eyes RE and LE of the viewer are disposed. The body 550 also has a predetermined thickness in a Z-axis direction between both eyes RE and LE of the viewer and the outer display panels 551 and 552.

Additionally, the body 550 may be provided, at an inner surface thereof, with first and second lens parts 450a and 450b configured to converge images into both eyes LE and RE of the viewer, respectively.

In some cases, the first lens part 450a and the first inner display panel 510 may be integrated into a single unit on the inner surface of the body 550, and similarly, the second lens part 450b and the second inner display panel 520 may be integrated into a single unit. Thus, these integrated units may be disposed together in the body 550.

Since, when the viewer's head moves, the display device 1000 moves together with the viewer's head, the vertical distance between each of the first and second inner display panels 510 and 520 and a corresponding one of both eyes LE and RE of the viewer is always constant regardless of movement of the viewer.

The display panel described with reference to each of FIGS. 2 to 7 may be configured as the outer display panels 551 and 552 of FIG. 9. The outer display panels 551 and 552 may be configured to selectively project images of both eyes of the viewer wearing the display device 2000 or to display a logo or a specific image. The outer display panels 551 and 552 display images separate from those displayed on the first and second inner display panels 510 and 520 corresponding to both eyes of the viewer.

Transmittance-variable barrier structures 220 or 320 are disposed at outermost edges of the outer display panels 551 and 552, respectively. Accordingly, when a viewer separate from a viewer wearing the display device 2000 views the display device 2000 from the outside, the transmittance-variable barrier structures 220 or 320 may sense external or ambient light and may prevent interference image perception of the separate viewer located outside the FOV range of the display device 2000. Here, interference images may be images outside the FOV range of the outer display panels 551 and 552 themselves, or may be images generated from the first and second inner display panels 510 and 520.

Accordingly, in the display device including the display panel of one or more embodiments of the present disclosure, images viewed by the viewer wearing the display device 2000 through the first and second inner display panels 510 and 520 disposed at the inner surface of the body 550 are not perceivable to viewers located outside the display device 2000.

The transmittance-variable barrier structures 220 or 320 are disposed at outermost edges of the display device 2000 and, as such, may easily sense external light through the barrier walls 225 or 325. At the same time, the transmittance-variable barrier structures 220 or 320 may absorb or block light at wavelengths corresponding to at least a part of the visible light spectrum, thereby preventing viewers outside the FOV range from perceiving interference images.

The display panel according to one or more embodiments of the present disclosure and the display device including the display panel include barrier walls made of an organic semiconductor material, thereby preventing viewers outside a predetermined viewing angle range from perceiving interference images.

The display panel according to one or more embodiments of the present disclosure and the display device including the display panel include electrode structures above and below the barrier walls. Accordingly, it may be possible to adjust an energy band gap by forming a vertical electric field across the barrier walls through the electrode structures. In accordance with the energy band gap adjustment, it may be possible to block and/or absorb light at wavelengths corresponding to at least a part of the visible light spectrum, thereby achieving implementation of a narrow viewing angle within a predetermined viewing angle range.

Embodiments of the present disclosure are not limited the display device as shown in FIGS. 8 and 9. For example, a display device according to one or more embodiments of the present disclosure can be implemented in a form separated from a body of the viewer (user) rather than a head mounted type. For example, an inner display panel may be disposed on an inner surface of a front glass which is viewed by a driver of the vehicle, and the display panel described in FIGS. 2 to 7 may be adjusted as an outer display panel on an outer surface of the front glass of the vehicle. Another viewer outside of the vehicle can watch images through the outer display panel which is disposed on the outer surface of the front glass of the vehicle. In this case, another viewer outside the vehicle may visually recognize images independent from images recognized by the driver inside the vehicle without interference, by the transmittance-variable barrier structure.

A display panel according to one or more embodiments of the present disclosure may comprise a substrate having a plurality of emission parts spaced apart from one another, a light emitting element on the substrate, a lens part on the light emitting element, a color conversion part on the lens part and a transmittance-variable barrier structure over the color conversion part, the transmittance-variable barrier structure comprising barrier walls respectively corresponding to regions among the plurality of emission parts.

In a display panel according to one or more embodiments of the present disclosure, each of the barrier walls may comprise a material having an energy band gap of 1.5 to 3.5 eV.

In a display panel according to one or more embodiments of the present disclosure, each of the barrier walls may comprise an organic semiconductor material variable in energy band gap in accordance with a wavelength of light incident on each of the barrier walls.

In a display panel according to one or more embodiments of the present disclosure, each of the barrier walls may have light absorption properties for at least a part of visible light wavelengths.

In a display panel according to one or more embodiments of the present disclosure, the transmittance-variable barrier structure may comprise a first electrode structure and a second electrode structure facing each other, and the barrier walls between the first electrode structure and the second electrode structure, the first electrode structure has a plate shape and the second electrode structure comprises divisional patterns respectively corresponding to the barrier walls surrounding the plurality of emission parts.

In a display panel according to one or more embodiments of the present disclosure, the barrier walls may be disposed in a form of islands for the plurality of emission parts, respectively. The barrier walls may be disposed in a form of annular islands surrounding the plurality of emission parts, respectively.

In a display panel according to one or more embodiments of the present disclosure, the first electrode structure may contact lower surfaces of the barrier walls and the second electrode structure may contact upper surfaces of the barrier walls, respectively.

In a display panel according to one or more embodiments of the present disclosure, the second electrode structure may have a greater area than an upper surface of the barrier wall corresponding to the divisional pattern.

In a display panel according to one or more embodiments of the present disclosure, a transparent insulating material may be filled between adjacent ones of the barrier walls and the transparent insulating material may have a height corresponding to a height of the barrier walls.

In a display panel according to one or more embodiments of the present disclosure, the color conversion part may comprise light shielding layers respectively corresponding to the barrier walls, and color filters respectively corresponding to the emission parts.

In a display panel according to one or more embodiments of the present disclosure, each of the barrier walls may have a smaller width than a corresponding one of the light shielding layers.

A display panel according to one or more embodiments of the present disclosure may further comprising a voltage difference applier to apply a voltage difference between the first electrode structure and the second electrode structure.

The voltage difference which is supplied by the voltage difference applier may be selectively controlled.

In a display panel according to one or more embodiments of the present disclosure, the light emitting element may comprise a plurality of first electrodes respectively corresponding to the plurality of emission parts, an intermediate layer, and a second electrode.

Edges of the plurality of first electrodes may be covered by a bank to expose the plurality of first electrodes of the plurality of emission parts.

At least one of the barrier walls may have a smaller width than the bank.

In a display panel according to one or more embodiments of the present disclosure, each of the barrier walls may have a cross-section having a trapezoidal shape having a longer top side than a bottom side.

A display panel according to one or more embodiments of the present disclosure may further comprise an encapsulation layer and a transparent protective layer between the light emitting element and the lens part.

In a display panel according to one or more embodiments of the present disclosure, each of the barrier walls may have a height of 2 to 5 μm.

A display device according to one or more embodiments of the present disclosure may comprise a body, inner display panels provided at an inner surface of the body to correspond to both eyes of a viewer, respectively, a display panel described above, the display panel being provided at an outer surface of the body, and a connector configured to interconnect opposite sides of the body.

The display panel according to one or more embodiments of the present disclosure and the display device using the display panel have the following effects.

It may be possible to prevent viewers located outside a predetermined viewing angle range from perceiving interference images, through inclusion of barrier walls including an organic semiconductor material.

Electrode structures are provided above and below the barrier walls. Accordingly, it may be possible to adjust an energy band gap by forming a vertical electric field across the barrier walls through the electrode structures. In accordance with the energy band gap adjustment, it may be possible to block and/or absorb light at wavelengths corresponding to at least a part of the visible light spectrum, thereby achieving implementation of a narrow viewing angle within a predetermined viewing angle range.

The structure disposed at the outermost side of the display panel may facilitate external light sensing through a transmittance-variable barrier wall structure. The sensitivity of the sensing may also be enhanced.

The organic semiconductor material does not cause outgassing by virtue of material characteristics thereof. Accordingly, the organic semiconductor material is advantageous for realization of eco-friendly devices. The organic semiconductor material also has advantages in that it is possible to achieve continuous process optimization. Thus, environmental/social/governance (ESG) goals may be achieved.

In the case in which a barrier wall with partial transmittance is provided, a configuration opaque in a predetermined viewing angle range may be omitted, leading to an enhancement in luminance within the predetermined viewing angle range. Furthermore, beyond the predetermined viewing angle range, transmission of interference view images through the barrier wall is prevented. Accordingly, it may be possible to prevent viewers located outside the predetermined viewing angle range from perceiving interference images and perceiving distorted images.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A display panel comprising:
a substrate having a plurality of emission parts spaced apart from one another;
a light emitting element on the substrate;
a lens part on the light emitting element;
a color conversion part on the lens part; and
a transmittance-variable barrier structure over the color conversion part, the transmittance-variable barrier structure comprising barrier walls that correspond to regions among the plurality of emission parts.

2. The display panel according to claim 1, wherein each of the barrier walls comprises a material having an energy band gap of 1.5 eV to 3.5 eV.

3. The display panel according to claim 1, wherein each of the barrier walls comprises an organic semiconductor material variable in an energy band gap in accordance with a wavelength of light incident on each of the barrier walls.

4. The display panel according to claim 1, wherein each of the barrier walls has light absorption properties for at least a part of visible light wavelengths.

5. The display panel according to claim 1, wherein:
the transmittance-variable barrier structure comprises a first electrode structure and a second electrode structure facing each other, and the barrier walls between the first electrode structure and the second electrode structure;
the first electrode structure has a plate shape; and
the second electrode structure comprises divisional patterns that correspond to the barrier walls surrounding the plurality of emission parts.

6. The display panel according to claim 5, wherein the barrier walls are in a form of islands for the plurality of emission parts.

7. The display panel according to claim 5, wherein:
the first electrode structure contacts lower surfaces of the barrier walls; and
the second electrode structure contacts upper surfaces of the barrier walls, the upper surfaces opposite to the lower surfaces.

8. The display panel according to claim 5, wherein the second electrode structure has, at each divisional pattern, a greater area than an upper surface of one of the barrier walls corresponding to each divisional pattern.

9. The display panel according to claim 5, wherein a transparent insulating material is between adjacent ones of the barrier walls, and wherein the transparent insulating material has a height corresponding to a height of the barrier walls.

10. The display panel according to claim 1, wherein the color conversion part comprises light shielding layers that correspond to the barrier walls, and color filters that correspond to the plurality of emission parts.

11. The display panel according to claim 10, wherein each of the barrier walls has a smaller width than a corresponding one of the light shielding layers.

12. The display panel according to claim 5, further comprising:
a voltage difference applier to apply a voltage difference between the first electrode structure and the second electrode structure,
wherein the voltage difference supplied by the voltage difference applier is selectively controlled.

13. The display panel according to claim 1, wherein:
the light emitting element comprises a plurality of first electrodes that correspond to the plurality of emission parts, an intermediate layer, and a second electrode;
edges of the plurality of first electrodes are covered by a bank to expose the plurality of first electrodes of the plurality of emission parts; and
at least one of the barrier walls has a smaller width than the bank.

14. The display panel according to claim 1, wherein each of the barrier walls has a cross-section having a trapezoidal shape having a top side that is longer than a bottom side opposite to the top side.

15. The display panel according to claim 1, further comprising:
an encapsulation layer and a transparent protective layer between the light emitting element and the lens part.

16. The display panel according to claim 1, wherein each of the barrier walls has a height of 2 μm to 5 μm.

17. A display device comprising:
a body;
inner display panels at an inner surface of the body to correspond to both eyes of a viewer;
a display panel according to claim 1, the display panel at an outer surface of the body; and
a connector configured to interconnect opposite sides of the body.
